(19) United States
(12) Patent Application Publication
(10) Pub. No.: US 2011/0114474 A1
(43) Pub. Date: May 19, 2011

(54) METHOD AND APPARATUS FOR DEPOSITION OF DIFFUSION THIN FILM

(76) Inventors: Sang-Youl Bae, Gyeonggi-do (KR); Si-Young Choi, Gyonggi-do (KR); Sung-Youp Chung, Gyeonggi-do (KR); Jung-Hyun Choi, Gyeonggi-do (KR)

(21) Appl. No.: 12/743,706

(22) PCT Filed: Nov. 22, 2007
(86) PCT No.: PCT/KR07/05918

§ 371 Date: May 19, 2010

(30) Foreign Application Priority Data
Nov. 20, 2007 (KR) 10-2007-0118741

(51) Int. Cl. C23C 14/34; C23C 14/22; C23C 14/14; C23C 14/54

(52) U.S. Cl. 204/192.15; 204/192.12; 204/192.38; 204/192.1; 204/298.02; 204/298.41; 204/298.06

(57) ABSTRACT

This invention relates to a method and apparatus for deposition of a diffused thin film, useful in the fabrication of semiconductors and for the surface DC-Bias coating of various tools. In order to coat the surface of a treatment object, such as semiconductors, various molded products, or various tools, with a thin film, one or more process factors selected from among a bias voltage, a gas quantity, an arc power, and a sputtering power are continuously and variably adjusted, whereby the composition ratio of the thin film which is formed on the surface of the treatment object not through a chemical reaction but through a physical method is continuously varied, thus manufacturing a thin film having high hardness. The composition ratio of the thin film to be deposited is selected depending on the end use thereof, thereby depositing the thin film having superior wear resistance, impact resistance, and heat resistance.

### TECHNICAL FIELD

The present invention relates to a method and apparatus for the deposition of a diffused thin film, useful in the fabrication of semiconductors and for the surface coating of various cutting tools, and more particularly, to a method and apparatus for the deposition of a diffusion thin film, in which, when a thin film is deposited not through chemical vapor deposition (CVD) but through physical vapor deposition (PVD), the composition ratio of the thin film is continuously variable in the depth direction thereof through resputtering using ion collision energy, and furthermore, the composition ratio of the thin film to be deposited is selected depending on the end use thereof, thereby improving the properties of the thin film and the deposition properties.

### BACKGROUND ART

Generally, deposition (or coating) of a thin film for the surface treatment of treatment objects, such as semiconductors, various molded products, or tools, requires the use of a PVD apparatus that is able to deposit a thin film having a thickness ranging from ones to tens of μm. Such an apparatus for depositing the thin film enables the formation of a thin film satisfying various requirements, including high hardness, wear resistance and impact resistance, depending on the end use and the surrounding environment.

Thus, thorough effort has been made to improve various deposition conditions, including thin film deposition methods, thin film materials, and supplied reactive gas, in order to provide thin films having good properties satisfying all of high hardness, wear resistance, impact resistance, and heat resistance.

In this regard, as illustrated in FIG. 1, when a treatment object is coated with a TiAlN thin film, in order to improve both wear resistance and impact resistance, which are contradictory to each other, not only aluminum nitride thin film layers (AlN: Layer 2, Layer 4), having high wear resistance and heat resistance, but also titanium nitride thin film layers (TiN: Layer 1, Layer 3), having high hardness and lubricating ability, or other thin film layers, which are not shown, may be stacked to thus realize a multilayer thin film 10 that is able to satisfy both wear resistance and impact resistance.

As mentioned above, when the AlN thin film layers (Layer 2, Layer 4) and the TiN thin film layers (Layer 1, Layer 3) are deposited to form a multilayer structure (Layer 1 to Layer 4), either wear resistance or impact resistance may be improved for respective layers (Layer 1, Layer 2, Layer 3, Layer 4). However, a junction region (or a split layer) may be formed between the respective layers (Layer 1, Layer 2, Layer 3, Layer 4), undesirably cracking and separating the multilayer thin film and making it impossible to significantly improve the properties of the thin film 10 as a complete multilayer structure.

### DISCLOSURE

### Technical Problem

Accordingly, the present invention has been made keeping in mind the above problems encountered in the related art, and the present invention provides a method and apparatus for the deposition of a diffused thin film, in which, when the surface of a treatment object, such as semiconductors, various molded products, or various cutting tools, is coated with the thin film, the composition ratio of the thin film is continuously variable in the depth direction thereof, and furthermore, the composition ratio of the thin film to be deposited is selected depending on the end use thereof, thereby improving the deposition properties of the thin film.

### Technical Solution

According to the present invention, a method of depositing a diffused thin film may include applying one or more process factors selected from among a bias voltage, a gas quantity, an arc power, and a sputtering power, which cause one or more thin film materials to be guided and deposited onto a treatment object, while continuously varying the one or more process factors to vary ion collision energy on the surface of the treatment object, thus causing resputtering of the composition of the thin film, thereby forming the diffused thin film.

As such, the one or more process factors, selected from among a bias voltage, a gas quantity, an arc power, and a sputtering power, may be continuously increased or decreased at least once for a time set by a user.

Also, the one or more process factors selected from among a bias voltage, a gas quantity, an arc power, and a sputtering power may be increased and then decreased, or are decreased and then increased, at least once for a time set by a user.

In the diffused thin film, which is guided and deposited onto the surface of the treatment object, one or more composition ratios of the diffused thin film may be continuously increased or decreased at least once in a depth direction of the thin film within a range of 0.2˜35% with respect to all or part of a thickness of the thin film.

Also, in the diffused thin film, which is guided and deposited onto the surface of the treatment object, one or more composition ratios of the diffused thin film may be increased and then decreased, or may be decreased and then increased, at least once in a depth direction of the thin film within a range of 0.2˜35% with respect to all or part of a thickness of the thin film.

The diffused thin film may be formed into a monolayer thin film or a multilayer thin film, and one or more composition ratios of the multilayer thin film may be continuously increased or decreased at least once in a depth direction of the thin film within a range of 0.2˜35%.

The multilayer thin film may be formed using an alloy target composed of a transition metal, including Ti, V, Cr, Cu, Y, Zr, Nb, or Mo and at least one metal selected from among Al, B, and Si, and a reactive gas comprising one or more selected from among nitrogen (N₂), a carbon group (C), including methane (CH₄) or acetylene (C₂H₂), and oxygen (O₂).

The waveform of power, including the bias voltage, the arc power, or the sputtering power, which is used to deposit various thin film materials, which are ionized, may be either a direct current (DC) waveform or a pulse waveform.

The diffused thin film may include crystal grains having a full width half maximum (FWHM) for (111) and (200) planes within a range of 0.7˜2.0.

In addition, according to the present invention, an apparatus for depositing a diffused thin film may include a vacuum chamber for depositing the diffused thin film on a treatment object received therein, a gas supplier for supplying a reactive gas into the vacuum chamber, a power supplier for supplying power to the vacuum chamber, a vacuum pump for creating a vacuum state inside the vacuum chamber, and a controller for variably controlling a magnitude of the power supplied to the vacuum chamber.

The controller may include a key input part for inputting set conditions including a bias voltage, a gas quantity, an arc power, and a sputtering power and a user command including a command for starting the deposition of the thin film.

The controller may further include a memory part for storing data input through the key input part.

The controller may further include a display part for externally displaying the set conditions input through the key input part and an extent of progress of the deposition of the thin film.

### Advantageous Effects

According to the present invention, in the method and apparatus for the deposition of a diffused thin film, when the surface of a treatment object, such as semiconductors, various molded products, or various tools, is coated with a thin film, one or more process factors, selected from among bias voltage, gas quantity, arc power, and sputtering power, are continuously and variably adjusted, so that the composition ratio of the thin film, which is deposited on the surface of the treatment object, is continuously changed, and furthermore, the composition ratio of the thin film to be deposited is selected depending on the end use thereof, thereby improving the deposition properties of the thin film.

In addition, according to the present invention, when the thin film is deposited on the treatment object, the process factor, such as bias voltage, gas quantity, arc power, and sputtering power, which are continuously variable, may be arbitrarily selected. Thus, even with the use of the same thin film material, it is possible to deposit a thin film that is suitable for the end use and the type of material.

### DESCRIPTION OF DRAWINGS

FIG. 1 illustrates a thin film obtained through the apparatus and method for the deposition of a thin film according to a conventional technique;

FIG. 2 illustrates the process of the deposition of a diffused thin film according to the present invention and the change in the deposition rate of the thin film thereby;

FIG. 3 illustrates the process of the deposition of a diffused thin film according to a first embodiment of the present invention and the thin film deposited thereby;

FIG. 4 illustrates the process of the deposition of a diffused thin film according to a second embodiment of the present invention and the thin film deposited thereby;

FIG. 5 illustrates the process of the deposition of a diffused thin film according to a third embodiment of the present invention and the thin film deposited thereby;

FIG. 6 is a flowchart illustrating the process of the deposition of the diffused thin film according to the present invention;

FIG. 7 schematically illustrates the apparatus for the deposition of a diffused thin film according to the present invention; and

FIG. 8 illustrates the construction of the apparatus for the deposition of a diffused thin film according to the present invention.

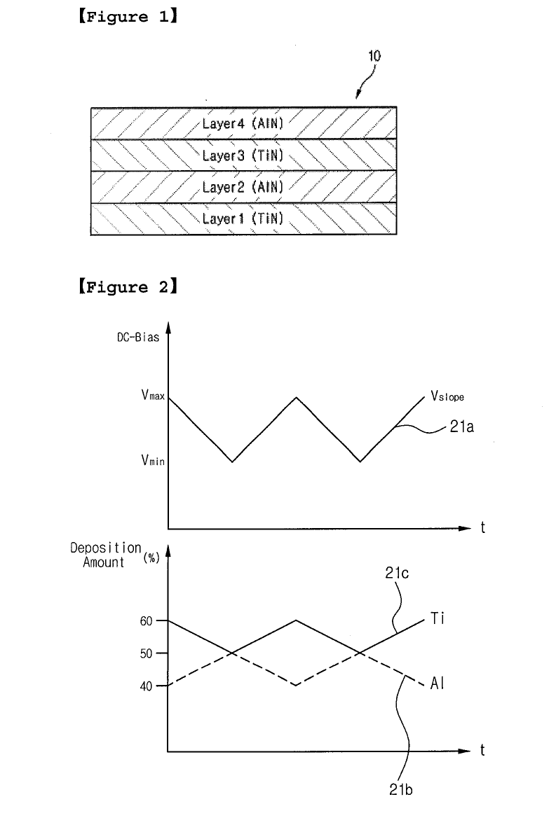

### BEST MODE

Hereinafter, a detailed description will be given of a method of depositing a diffused thin film according to the present invention with reference to the appended drawings.

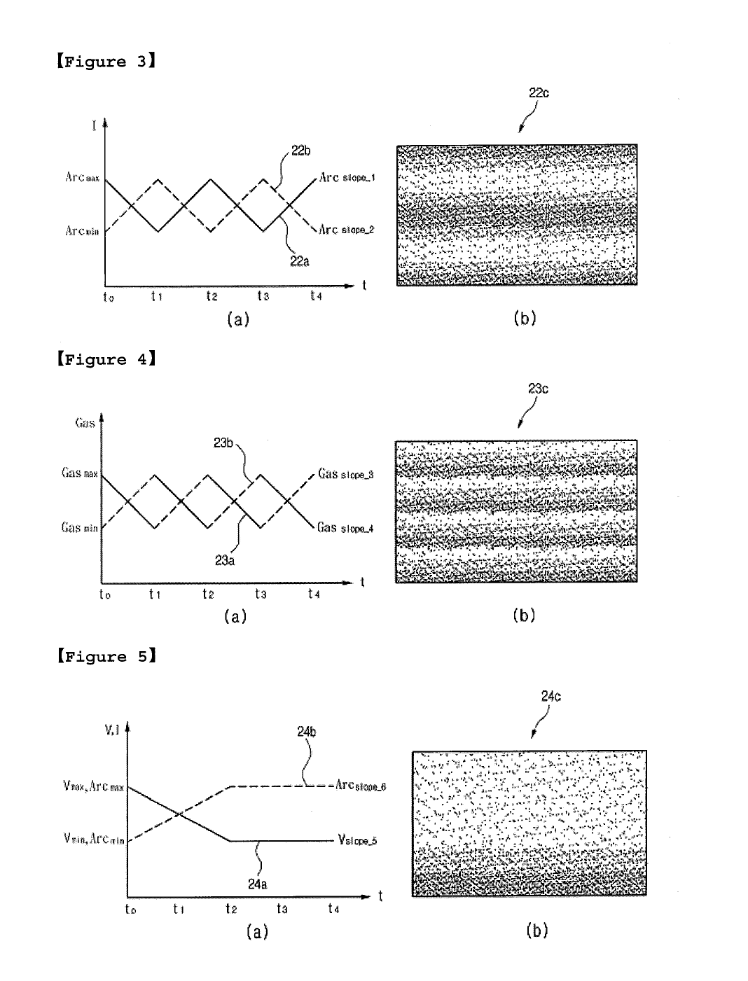

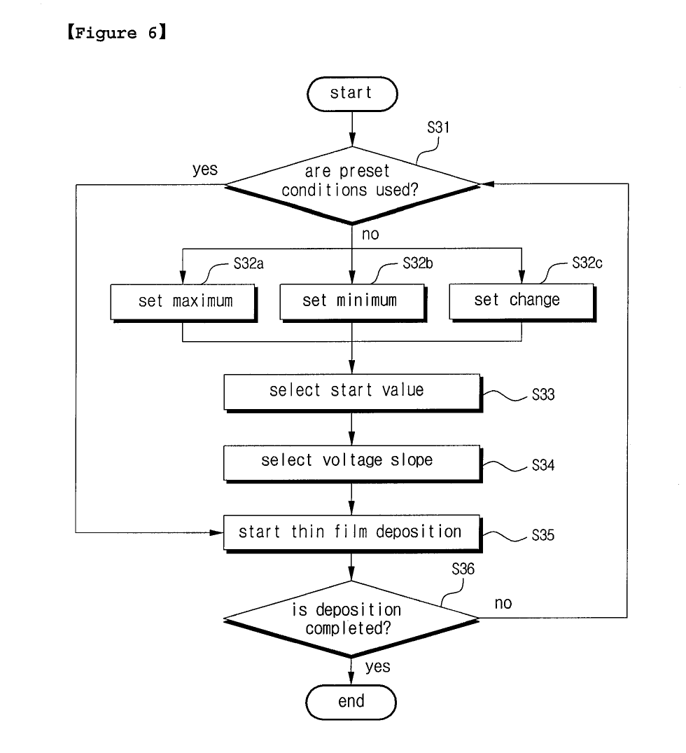

FIG. 2 illustrates the process of the deposition of a diffused thin film according to the present invention and the change in the deposition rate of the thin film thereby, FIG. 3 illustrates the process of the deposition of a diffused thin film according to a first embodiment of the present invention and the thin film deposited thereby, FIG. 4 illustrates the process of the deposition of a diffused thin film according to a second embodiment of the present invention and the thin film deposited thereby, FIG. 5 illustrates the process of the deposition of a diffused thin film according to a third embodiment of the present invention and the thin film deposited thereby, and FIG. 6 is a flowchart illustrating the process of the deposition of the diffused thin film according to the present invention.

According to the present invention, there are provided a method and apparatus for the deposition of a diffused thin film through PVD, that is, physical resputtering using ion collision energy, instead of CVD for diffusing a plurality of compositions through a chemical reaction, at the time of coating the surface of a treatment object, such as semiconductors and various cutting tools, with a thin film.

In the present invention, upon the deposition of the thin film, the change in the composition of the thin film is continuously variable in a depth direction, thus forming a diffused thin film. The thin film thus obtained plays a function as a super multilayer having at least hundreds of layers, thereby exhibiting higher hardness.

Further, in order to form a thin film comprising two components or more, in the case where the composition ratio of the thin film is continuously variable, not only high hardness, but also wear resistance, impact resistance and heat resistance may be improved. Also, the start point of the increase or decrease in the composition of the thin film to be deposited is selected depending on the end use thereof, thus enabling the formation of a thin film having desired shapes and properties.

Therefore, in the present invention, with the goal of variably adjusting the composition ratio of the thin film, which is formed on the surface of the treatment object, one or more process factors, selected from among bias voltage, gas quantity, arc power, and sputtering power, required to guide and deposit the thin film material onto the treatment object, should be continuously variable for a time period set by a user.

When one or more process factors selected from among bias voltage, gas quantity, arc power, and sputtering power are continuously varied, the change in the composition of the thin film is controlled so that it is increased or decreased at least once in the depth direction thereof for the time period set by a user.

Further, as one or more process factors selected from among bias voltage, gas quantity, arc power, and sputtering power are independently and continuously adjusted, specifically, as only the bias voltage, only the arc or sputtering power, or only vacuum conductance in response to the control of the gas quantity to be supplied is adjusted, the collision energy of ions of the thin film, which is formed on the surface of the treatment object, is changed, and the degree of resputtering varies depending on the size of the ions, thus changing the composition ratio of the thin film as in a multilayer thin film. In this way, the change in the composition of the thin film may be adjusted, and it is thus possible to form an optimal thin film suitable for the shape and properties of treatment objects formed of various materials.

The thin film, which is capable of being deposited to a thickness ranging from ones to tens of μm, is required to exhibit various properties, including high hardness, wear resistance, toughness, impact resistance and heat resistance, depending on the end use and the surrounding environment.

That is, in the case where a light thin film having a thickness ranging from ones to tens of μm is applied using a single-component metal target, it has higher hardness than a monolayer thin film having the same thickness. Hardness is enhanced in proportion to the increase or decrease cycle of the composition ratio of the diffused thin film having a multilayer structure, which is not shown, in which the composition of the thin film continuously varies in a depth direction thereof.

The number of layers of the diffused thin film increases in proportion to the rpm of a turntable during the thin film coating time.

FIG. 2 illustrates the process of deposition of the diffused thin film according to the present invention and the change in the deposition rate of the thin film thereby.

As illustrated in FIG. 2, in the method of depositing the diffused thin film according to the present invention, arc, sputtering, or bias voltage, which causes various thin film materials (also called a target or an evaporation source), which are ionized, to be guided and deposited onto a treatment object, such as substrates and various molded products, is continuously varied for a predetermined time set by a user, including all or part of a thin film deposition time.

For example, using an ionized thin film material composed of titanium (Ti) and aluminum (Al) at a ratio of 5:5 by at % and an arc source for supplying nitrogen gas as a reactive gas, various treatment objects are coated with a thin film. As the bias voltage is continuously varied for the set time, deposition rates 21b, 21c for depositing the titanium and aluminum present in an ion state in a vacuum chamber 50 on a treatment object are also variable.

That is, the titanium and aluminum ions present at a ratio of about 5:5 in the vacuum chamber 50 should also be deposited at a ratio of about 5:5 on the treatment object.

However, as shown in the voltage slope Vₛₗₒₚₑ, 21a, when the bias voltage is increased and high voltage is applied, aluminum particles having a relatively small size collide with the treatment object at a speed greater than the titanium particles and are thus deposited, followed by the continuous collision and deposition of the aluminum particles and the titanium particles. The deposited aluminum particles are subject to rebounding (hereinafter, referred to as “resputtering”) to a degree relatively greater than the titanium particles. Although the deposition rates are slightly different depending on the magnitude of the bias voltage, the aluminum deposition rate 21b and the titanium deposition rate 21c have a ratio therebetween of about 4:6.

Conversely, when the bias voltage is decreased and low voltage is applied, the collision speed of respective particles is also decreased, and thus the resputtering of the deposited aluminum particles is reduced. Thereby, the aluminum deposition rate is increased from 40% to 50%, and the titanium deposition rate is decreased from about 60% to 50%, resulting in a ratio of aluminum to titanium of about 5:5.

Therefore, when the bias voltage is continuously varied from high voltage to low voltage or from low voltage to high voltage for a predetermined time, the aforementioned change occurs continuously, thus making it possible to coat a mixture thin film exhibiting all of the advantages of aluminum and titanium. As well, because the bias voltage is slowly and continuously changed, a split layer is not generated in the thin film, and specifically, using a physical method which does not cause interlayer separation, a diffused thin film may be formed, thus improving the properties thereof more and more.

Even in the case where the arc and sputtering power and the nitrogen gas are applied in variable amounts, the resputtering effect and the mean free path are changed as in the application of the bias voltage, thus forming a diffused thin film having the composition ratio varying in the depth direction thereof.

Further, even in the case where one or more process factors selected from among the bias voltage, the arc power, the sputtering power, and the gas quantity are continuously varied, a thin film, having high hardness, wear resistance, toughness, impact resistance and heat resistance, may be manufactured.

Furthermore, even in the case where two or more reactive gases are simultaneously supplied in addition to the one- or multi-component target, the degree of resputtering of the composition varies depending on the amount of the reactive gas, and thus the composition of the thin film becomes different in the depth direction thereof.

In the diffused thin film, which is guided and deposited onto the treatment object, it is preferred that one or more composition ratios thereof be continuously increased or decreased at least once in the depth direction within the range of 0.2˜35% with respect to all or part of the thickness of the thin film. When the composition ratio of the thin film is less than 0.2%, wear resistance and toughness are very similar to those of the case in which there is no difference in the composition. On the other hand, when the composition ratio of the thin film is varied such that it exceeds 35%, the stress of the thin film is increased, and undesirably, when a thick film having a thickness of 10 μm or more is applied, part thereof may be stripped.

If one or more composition ratios of the thin film fall within the range of 0.2˜35%, the composition ratio of the thin film is not continuously increased or decreased, but it is repeatedly increased and then decreased, or is repeatedly decreased and then increased, at least hundreds of times, to thus form a thick film. In this case, the film thus obtained has high quality, and does not exhibit stripping. Compared to a thin film having an unchanged composition ratio, a diffused thin film having many changes in the composition thereof is not stressed, thus facilitating the manufacture of the thin film to a thickness of tens of μm.

Preferably, when the composition ratio of the thin film is increased or decreased within the range of 20%, hardness and thin film properties are improved. More preferably, when the composition ratio of the thin film is increased or decreased within the range of 10%, the hardness and thin film properties are maximized.

Generally, in the case where a cutting tool is subjected to light coating, a film is formed in the growth direction of the (111) plane or the (200) plane, depending on the end use, and is then coated more thickly to have a thickness up to tens of μm from conventional ones of μm to improve wear resistance. However, when the film is formed too thick in this way, it has a columnar crystal structure in a single direction, so that the residual stress of the thin film is increased in proportion to the thickness of the thin film, making it undesirably easy to strip the film.

In contrast, according to the present invention, in the case where the diffused thin film is formed, the residual stress of the thin film may be controlled. For example, for the bias voltage, when a plurality of cycles of continuous decrease from high voltage to low voltage and then increase is repeated, the growth direction is converted from (111) to (200) and then to (111) in proportion to the voltage, and thus the thin film is prevented from growing in a columnar crystal structure in a single direction and the respective layers thereof have a fine structure.

Further, as the results of X-ray analysis, the crystal grains of the diffused thin film exhibit an amorphous phase (the crystalline peak is broadened) within the range of full width half maximum (FWHM) for the (111) and (200) planes of 0.7˜2.0°. Upon cutting, the fracture surface is observed in the form of a sloped surface having resistance, but is not cut vertically.

FIG. 3 illustrates the process of the deposition of a diffused thin film according to a first embodiment of the present invention and the thin film deposited thereby, FIG. 4 illustrates the process of the deposition of a diffused thin film according to a second embodiment of the present invention and the thin film deposited thereby, and FIG. 5 illustrates the process of the deposition of a diffused thin film according to a third embodiment of the present invention and the thin film deposited thereby.

As is apparent from (a) of FIG. 3, in the method of depositing the diffused thin film according to the present invention, as shown in an arc current slope 1 Arcₛₗₒₚₑ₋₁ 22a and an arc current slope 2 Arcₛₗₒₚₑ₋₂ 22b, the arc current is repeatedly increased and decreased (high current->low current->high current->low current) for all or part of the thin film deposition time.

Accordingly, as shown in (b) of FIG. 3, the deposited thin film 22c does not exhibit a split structure, but has a diffused structure, thus preventing the interlayer separation of the thin film 22c and simultaneously satisfying various properties, including toughness, wear resistance, and impact resistance.

As well, the arc current is continuously variable for a predetermined time. In order to improve the hardness and wear resistance of the thin film, as shown in the arc current slope 1 22a, the arc current is preferably varied from high current to low current. In order to improve the toughness of the thin film 22c, the arc current is preferably varied from low current to high current, as shown in the arc current slope 2 22b.

In addition, as is apparent from (a) of FIG. 4, in the method of depositing the diffused thin film according to the present invention, as shown in a gas quantity slope 3 Gasₛₗₒₚₑ₋₃ 23a and a gas quantity slope 4 Gasₛₗₒₚₑ₋₄ 23b, the reactive gas quantity is repeatedly decreased (high->low, high->low) or repeatedly increased (low->high, low->high) for all or part of the thin film deposition time, thus changing the vacuum conductance during the process.

Accordingly, as seen in (b) of FIG. 4, the thin film is deposited in the form of a multilayer thin film. Respective layers thereof have a diffused structure, thus simultaneously satisfying various properties including toughness, wear resistance and impact resistance. However, the interlayer separation properties of the thin film 23c may be slightly decreased compared to FIG. 3.

In addition, as is apparent from (a) of FIG. 5, in the method of depositing the diffused thin film according to the present invention, as shown in a voltage slope 5 Vₛₗₒₚₑ₋₅ 24a and an arc current slope Arcₛₗₒₚₑ₋₆ 24b, while the bias voltage is repeatedly decreased and maintained (high voltage->low voltage ->low voltage), the arc current is repeatedly increased and maintained (low current->high current->high current), for all or part of the thin film deposition time.

Accordingly, as seen in (b) of FIG. 5, the deposited thin film does not exhibit a split structure, but has a diffused structure, thus preventing the interlayer separation of the thin film 24c and simultaneously satisfying various properties, including toughness, wear resistance and impact resistance, at the same time.

In particular, as the process factor, such as bias voltage, gas quantity, arc and sputtering power, is more and more slowly increased or decreased, the force of cohesion of the thin film may be further increased.

As mentioned above, the diffused thin film may be formed into a monolayer thin film or a multilayer thin film. In this case, to improve the high-temperature hardness and heat resistance, the composition of the target includes an alloy target having a plurality of compositions, consisting of a transition metal such as titanium (Ti), vanadium (V), chromium (Cr), copper (Cu), yttrium (Y), zirconium (Zr), niobium (Nb), or molybdenum (Mo), and a metal such as aluminum (Al), boron (B), or silicon (Si).

The reactive gas, which reacts with the alloy target, is typically exemplified by nitrogen (N₂). In addition, a reactive gas, including a carbon group (C), such as methane (CH₄) or acetylene (C₂H₂), or oxygen (O₂), may be selectively combined therewith for use.

That is, in the light thin film composed of an alloy target having a multi-component composition and a plurality of reactive gases, as one or more process factors selected from among bias voltage, gas quantity, arc power, and sputtering power are continuously varied, the composition ratio of the thin film is changed in the depth direction thereof depending on the size of the metal or gas ion of the composition, thereby obtaining a diffused thin film, the composition of which is sequentially varied at least once within the range of 0.2˜35%.

In this way, when one or more process factors, selected from among bias voltage, gas quantity, arc power, and sputtering power, are continuously varied for the set time, the change in the composition ratio of the thin film is increased or decreased at least once, or is increased or decreased at least once, in the depth direction thereof for the time set by a user, thus forming the diffused thin film, which functions as a super multilayer composed of at least hundreds of layers, which are not shown, thereby improving high hardness and wear resistance, toughness and impact resistance. Depending on the end use, the start point of the increase or decrease in the composition of the thin film to be deposited is selected, thus enabling the formation of the thin film suitable for the shape and properties of the treatment object.

Below, with reference to FIG. 6, the thin film deposition process through the method of deposition of a diffused thin film according to the present invention is described.

As illustrated in FIG. 6, whether preset conditions, related to the maximums and minimums of bias voltage, arc current, and reactive gas quantity, and changes thereof, are used unchanged is checked at step S31. When the use of the preset conditions without change is selected by a user, thin film deposition starts according to the preset conditions at step S35.

Otherwise, in the case where the thin film is intended to be deposited under different conditions, the maximums and minimums of bias voltage, arc current, and reactive gas quantity, and changes thereof are set through key input by a user at steps S32a, S32b, and S32c.

After the conditions are set at steps S32a, S32b, and S32c, the initial start values of the bias voltage, the arc current, and the reactive gas quantity are selected depending on the end use of the thin film, at step S33. That is, whether the bias voltage is varied from low voltage to high voltage or from high voltage to low voltage is selected. Further, whether the arc current to be applied to the target is varied from low current to high current or from high current to low current is selected, and the reactive gas quantity is selected, at step S33.

After the initial start values are selected at step S33, subsequent conditions, for example, a voltage slope, a current slope, and a slope for the reactive gas quantity, are selected at step S34. For instance, in the case of the slope, as shown in FIGS. 3 to 5, among various slopes 22a, 22b, 23a, 23b, 24a, 24b, any one is selected. In addition to the above slope examples, a slope in a continuously variable form having various slope gradients may be set and selected, which will be apparent to those skilled in the art.

After the above conditions are selected at step S34, thin film deposition starts at step S35. Whether the deposition is completed is checked. If the deposition is completed, the process is terminated. If the deposition is not completed, the above routine is repeated.

In this way, depending on the selection of the user, as the bias voltage, the arc current, and the reactive gas quantity are set, the thin film may be formed on the surface of various types of treatment objects. Thus, the thin film thus obtained has a diffused structure, so that the thin film simultaneously satisfies various properties including toughness, wear resistance, and impact resistance while preventing the interlayer separation thereof, in order to be adapted to the end use.

Then, the apparatus for the deposition of a diffused thin film according to the present invention is described below with reference to the appended drawing.

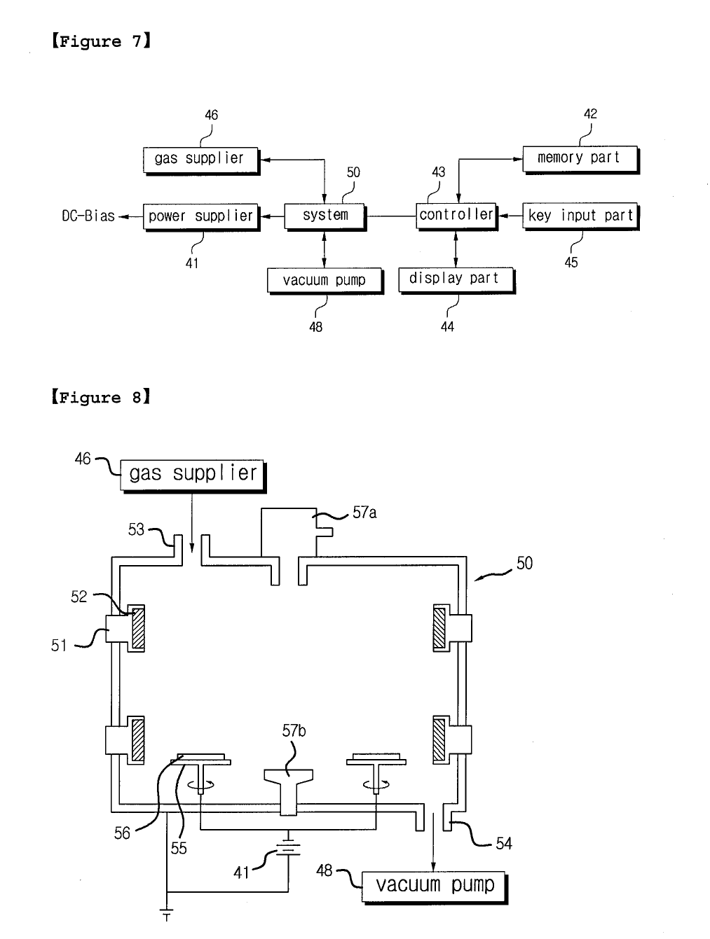

FIG. 7 schematically illustrates the apparatus for the deposition of a diffused thin film according to the present invention, and FIG. 8 illustrates an embodiment of the apparatus for the deposition of a diffused thin film according to the present invention.

As illustrated in FIG. 7, the apparatus for depositing the thin film includes a vacuum chamber (or system) 50 for depositing a thin film on a treatment object (or a substrate) 56, a gas supplier 46 for supplying a reactive gas into the vacuum chamber 50 using an MFC (Mass Flow Controller), a power supplier 41 for supplying power to the vacuum chamber 50, a vacuum pump 48 for creating a vacuum state inside the vacuum chamber 50, and a controller 43 for variably controlling the magnitude of the power supplied to the vacuum chamber 50.

Examples of the apparatus for deposition of the thin film include various thin film deposition apparatuses able to conduct PVD, including ion plating, sputtering, and combinations thereof. Below, an ion plating apparatus using an arc source is illustratively described below.

As illustrated in FIG. 8, the vacuum chamber 50 includes a reactive gas inlet 53 at the top thereof to supply the reactive gas from the gas supplier 46 into the vacuum chamber 50 using the MFC (not shown). At the bottom thereof, a reactive gas outlet 54 is provided to discharge the reactive gas or to create a vacuum state inside the vacuum chamber 50 using the vacuum pump 48.

Further, the vacuum chamber 50 includes one or more cathodic targets or evaporation sources 52 provided at one side thereof, arc evaporation sources 51 for melting and evaporating the targets or evaporation sources 52 using arc discharge, and a substrate holder 55 for supporting a substrate (or treatment object) 56 on which ions are deposited and applying bias voltage to attract fine particles, which are ionized in the targets or evaporation sources 52.

The reactive gas outlet 54 of the vacuum chamber 50 is connected to the vacuum pump 48 to maintain and control the vacuum state inside the vacuum chamber 50.

Furthermore, before the thin film is deposited on the substrate 56, in order to clean the surface of the substrate 56 with ions to thus increase the force of cohesion and uniformity of the thin film, an HCD (Hollow Cathode Discharge) gun 57a and a hearth 57b, to which negative (−) potential and positive (+) potential are applied, respectively, may be provided, and an auxiliary anode (not shown) may be disposed between the hearth 57b and the substrate 56, as necessary.

The power supplier 41 functions to supply the power, such as bias voltage or arc current, to the vacuum chamber 50 depending on the set conditions.

The controller 43 may be provided with a key input part 45, a memory part 42, and a display part 44. The key input part 45 functions to input the conditions, including the bias voltage, the gas quantity, the arc power, and the sputtering power, and user commands, including the start of the deposition of the thin film, and the memory part 42 functions to store the information data related to the voltage, the gas quantity, the arc power and the sputtering power, which are set using the key input part 45. The display part 44 functions to externally display the set conditions, which are input through the key input part 45, the preset conditions, and the extent of progress of the thin film deposition.

Thus, the controller 43 plays a role in storing the set conditions, input through the key input part 45, into the memory part 42, processing the data so that it is readable from the memory part 45, and controlling the output of the power supplier 41 according to the set conditions.

Accordingly, as one or more process factors selected from the bias voltage, the gas quantity, the arc power, and the sputtering power are continuously and variably adjusted, the deposited thin film does not exhibit a split structure, but has a diffused structure, thus preventing the interlayer separation of the thin film and simultaneously satisfying various properties including toughness, wear resistance and impact resistance. As well, it is possible to select the start voltage at which to deposit the thin film so that it is suitable for the end use thereof. When a monolayer thin film, such as TiN, TiCN, TiSiN, TiAlN, AlTiN, AlCrN, or TiAlSiCrN, or a multilayer thin film, such as TiN/TiAlN, CrN/TiAlCrN, TiN/TiSiN, TiAlN/TiCrAlN, or TiAlN/TiAlSiN, is formed, one or more thin films may be deposited in the form of a diffused thin film, and the composition ratio thereof is sequentially variable at least once within the range of 0.2˜35%.

Although the preferred embodiments of the present invention, with regard to the method of deposition of the thin film, have been disclosed for illustrative purposes, those skilled in the art will appreciate that various modifications, additions and substitutions are possible, without departing from the scope and spirit of the invention.

In particular, the thin film deposition is specified for coating various treatment objects, but the present invention is not limited thereto. The present invention may be applied to the fabrication of semiconductors, including gate, bit line, insulating layers (or spacers), and vias, requiring thin film deposition, which will be apparent to those skilled in the art.

In the present invention, the arc and sputtering power are exemplarily represented by a direct current waveform and a pulse waveform. However, through continuous increase or decrease for a predetermined time, even using alternating current (AC) type power, including radio frequency (RF) power, in addition to variation of the numerical values, including the variable voltage, the maximum, the minimum, the difference between the maximum and the minimum, and the cycle, it is possible to deposit the thin film, which will be apparent to those skilled in the art.

It should also be understood that the foregoing, relating only to the scope of the invention, is defined by the appended claims rather than by the description preceding them, and all changes that fall within meets and bounds of the claims, or equivalence of such meets and bounds are therefore intended to embraced by the claims.

### INDUSTRIAL APPLICABILITY

As described hereinbefore, the present invention pertains to a method and apparatus for the deposition of a diffused thin film, useful in the fabrication of semiconductors and for the surface coating of various cutting tools, and more particularly, to a method and apparatus for the deposition of a thin film, in which, when a thin film is deposited not through CVD but through PVD, the composition ratio of the thin film is continuously variable in the depth direction thereof through resputtering using ion collision energy, and furthermore, the composition ratio of the thin film to be deposited is selected depending on the end use thereof, thereby improving the properties of the thin film and the deposition properties.

1. A method of depositing a diffused thin film, comprising applying one or more process factors selected from among a bias voltage, a gas quantity, an arc power, and a sputtering power, which cause one or more thin film materials to be guided and deposited onto a treatment object, while continuously varying the one or more process factors to vary an ion collision energy on a surface of the treatment object, thus causing resputtering of a composition of the thin film, thereby forming the diffused thin film.

2. The method according to claim 1, wherein the one or more process factors, selected from among a bias voltage, a gas quantity, an arc power, and a sputtering power, are continuously increased or decreased at least once for a time set by a user.

3. The method according to claim 1, wherein the one or more process factors selected from among a bias voltage, a gas quantity, an arc power, and a sputtering power are increased and then decreased, or are decreased and then increased, at least once for a time set by a user.

4. The method according to claim 1, wherein, in the diffused thin film, which is guided and deposited onto the surface of the treatment object, one or more composition ratios of the diffused thin film are continuously increased or decreased at least once in a depth direction of the thin film within a range of 0.2˜35% with respect to all or part of a thickness of the thin film.

5. The method according to claim 1, wherein, in the diffused thin film, which is guided and deposited onto the surface of the treatment object, one or more composition ratios of the diffused thin film are increased and then decreased, or are decreased and then increased, at least once in a depth direction of the thin film within a range of 0.2˜35% with respect to all or part of a thickness of the thin film.

6. The method according to claim 1, wherein the diffused thin film is formed into a monolayer thin film or a multilayer thin film, and one or more composition ratios of the multilayer thin film are continuously increased or decreased at least once in a depth direction of the thin film within a range of 0.2˜35%.

7. The method according to claim 6, wherein the multilayer thin film is formed using an alloy target composed of a transition metal, including Ti, V, Cr, Cu, Y, Zr, Nb, or Mo and at least one metal selected from among Al, B, and Si, and a reactive gas comprising one or more selected from among nitrogen (N₂), a carbon group (C), including methane (CH₄) or acetylene (C₂H₂), and oxygen (O₂).

8. The method according to claim 1, wherein a waveform of power, including the bias voltage, the arc power, or the sputtering power, which is used to deposit various thin film materials, which are ionized, is either a direct current (DC) waveform or a pulse waveform.

9. The method according to claim 1, wherein the diffused thin film comprises crystal grains having a full width half maximum (FWHM) for (111) and (200) planes within a range of 0.7˜2.0.

10. An apparatus for depositing a diffused thin film, comprising:
a vacuum chamber for depositing the diffused thin film on a treatment object received therein;
a gas supplier for supplying a reactive gas into the vacuum chamber;
a power supplier for supplying power to the vacuum chamber;
a vacuum pump for creating a vacuum state inside the vacuum chamber; and
a controller for variably controlling a magnitude of the power supplied to the vacuum chamber.

11. The apparatus according to claim 10, wherein the controller comprises a key input part for inputting set conditions including a bias voltage, a gas quantity, an arc power, and a sputtering power and a user command including a command for starting the deposition of the thin film.

12. The apparatus according to claim 11, wherein the controller further comprises a memory part for storing data input through the key input part.

13. The apparatus according to claim 11, wherein the controller further comprises a display part for externally displaying the set conditions input through the key input part and an extent of progress of the deposition of the thin film.

14. The method according to claim 4, wherein the diffused thin film comprises crystal grains having a full width half maximum (FWHM) for (111) and (200) planes within a range of 0.7˜2.0.

15. The method according to claim 5, wherein the diffused thin film comprises crystal grains having a full width half maximum (FWHM) for (111) and (200) planes within a range of 0.7˜2.0.

16. The method according to claim 6, wherein the diffused thin film comprises crystal grains having a full width half maximum (FWHM) for (111) and (200) planes within a range of 0.7˜2.0.
